(19) United States
(12) Patent Application Publication
(10) Pub. No.: US 2019/0219853 A1
(43) Pub. Date: Jul. 18, 2019

(54) COA SUBSTRATE, MANUFACTURING METHOD THEREFOR, DISPLAY PANEL, AND DISPLAY DEVICE

(71) Applicants: FUZHOU BOE OPTOELECTRONICS TECHNOLOGY CO., LTD., Fuzhou, Fujian (CN); BOE TECHNOLOGY GROUP CO., LTD., Beijing (CN)

(72) Inventors: Jiamin LIAO, Beijing (CN); Xi CHEN, Beijing (CN); Yao LIU, Beijing (CN); Zongxiang LI, Beijing (CN); Shijian LUO, Beijing (CN); Yang YU, Beijing (CN); Bo HU, Beijing (CN); Heyuan QIU, Beijing (CN)

(21) Appl. No.: 16/318,640

(22) PCT Filed: May 14, 2018
(86) PCT No.: PCT/CN2018/086713

§ 371 Date: Jan. 17, 2019

(30) Foreign Application Priority Data
Jun. 12, 2017 (CN) 201710439255.1

(51) Int. Cl. G02F 1/1362; G02F 1/1368; H01L 27/12

(52) U.S. Cl. CPC G02F 1/1362; G02F 1/136209; G02F 1/1368; G02F 1/136227; G02F 1/136286; G02F 2001/136222; H01L 27/1262

(57) ABSTRACT

A COA substrate, a manufacturing method therefore, a display panel, and a display device. The COA substrate includes a base substrate, a thin-film transistor provided on one side of the base substrate, and a color filter film provided on the other side of the base substrate facing away from the thin-film transistor.

The present application claims priority to the Chinese patent application No. 201710439255.1, filed on Jun. 12, 2017, the entire disclosure of which is incorporated herein by reference as part of the present application.

### TECHNICAL FIELD

Embodiments of the present disclosure relate to a COA substrate and a manufacturing method thereof, a display panel and a display device.

### BACKGROUND

With the development of liquid crystal display technology, narrow-frame or frameless liquid crystal display devices have become the mainstream trend of high-quality display devices. In order to eliminate deviation when forming a cell by assembling a color filter substrate with an array substrate, a color filter film and a black matrix are generally formed on the array substrate in the same layer by using a COA (color filter on array) technology to form a COA substrate.

Generally, a COA substrate includes a base substrate, and a gate electrode, a gate insulation layer, an active layer, a source-drain electrode, a passivation layer, a color filter film, a pixel electrode, an alignment layer, and the like which are stacked on the base substrate. The passivation layer and the color filter film are provided therein with a via hole at a region corresponding to the source-drain electrode, and the pixel electrode is connected to the source-drain electrode through the via hole.

However, compared with a conventional array substrate, a COA substrate has a color filter film between a source-drain electrode and a pixel electrode, which increases a thickness of a film formed between the source-drain electrode and the pixel electrode, resulting in a deep via hole. The via hole is generally formed in a tapered shape, the deeper the via hole, the larger the diameter of the via hole at the end near the pixel electrode. Therefore, when a pixel electrode is formed on a color filter film, if a via hole having a large depth and a large diameter is formed, after the pixel electrode is formed, a deeper hole with larger diameter would be formed at a region where the via hole is located. In this case, when alignment liquid is applied on the pixel electrode to form an alignment layer, the alignment liquid applied around the hole is easily spread into the via hole, and the alignment liquid coated at other positions is spread towards the via hole, resulting in forming an alignment layer having an uneven thickness after the alignment liquid is gradually spread and cured, causing uneven display brightness or display chromaticity of the liquid crystal display device.

### SUMMARY

The embodiments of the present disclosure provide a color filter on array (COA) substrate comprising a base substrate, a thin film transistor being on a side of the base substrate, a color filter film being on the other side of the base substrate facing away from the thin film transistor.

Based on the COA substrate described above, an embodiment of the present disclosure provides a manufacturing method of a COA substrate, comprising: providing a base substrate, forming a thin film transistor on one side of the base substrate; forming a color filter film on the other side of the base substrate.

Based on the COA substrate described above, another embodiment of the present disclosure provides a display panel comprising the COA substrate provided by the above-mentioned technical solutions.

Based on the display panel described above, another embodiment of the present disclosure provides a display device comprising the display panel provided by the embodiment of the present disclosure.

### BRIEF DESCRIPTION OF THE DRAWINGS

In order to clearly illustrate the technical solution of the embodiments of the present disclosure, the drawings of the embodiments will be briefly described in the following: it is obvious that the described drawings are only related to some embodiments of the disclosure and thus are not limitative of the present disclosure.

FIG. 1 is a schematic view of a structure of a COA substrate provided by an embodiment of the present disclosure;

FIG. 2 is a schematic view of an area dividing manner of a COA substrate provided by an embodiment of the present disclosure;

FIG. 3 is a first cross-sectional view taken along line C-C of a COA substrate provided by an embodiment of the present disclosure;

FIG. 4 is a second cross-sectional view taken along line C-C of a COA substrate provided by an embodiment of the present disclosure;

FIG. 5 is a top plan view of a part of a COA substrate provided by an embodiment of the present disclosure;

FIG. 6 is a schematic cross-sectional view taken along line D-D of a COA substrate provided by an embodiment of the present disclosure;

FIG. 7 is a cross-sectional view taken along line E-E of a COA substrate provided by an embodiment of the present disclosure;

FIG. 8 is a cross-sectional view taken along line F-F of a COA substrate provided by an embodiment of the present disclosure;

FIG. 9 is a flow chart of a manufacturing method of a COA substrate provided by an embodiment of the present disclosure.

Reference numerals: 1—base substrate, 2—thin film transistor, 3—color filter film, 4—blue color filter layer, 5—green color filter layer, 6—red color filter layer, 21—common electrode, 22—gate electrode, 23—insulation layer, 24—active layer, 25—source-drain electrode, 26—passivation layer, 7—light shielding metal, 8—light shielding layer, 9—backlight.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

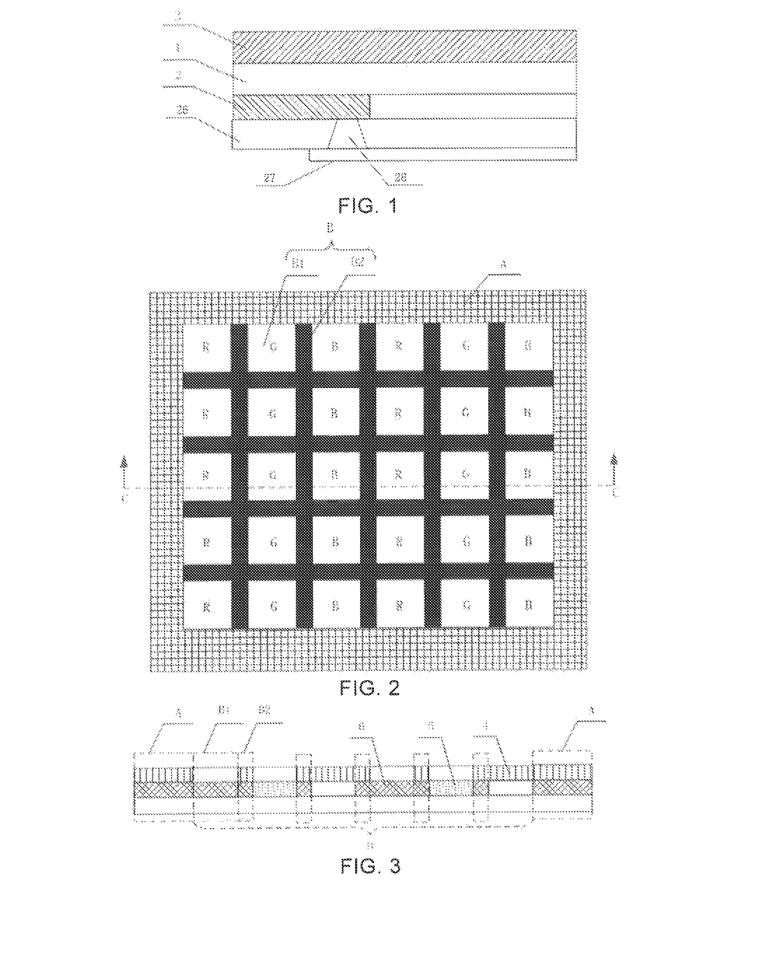

Referring to FIG. 1, a COA substrate provided by an embodiment of the present disclosure includes a base substrate 1, a thin film transistor 2 is on a side of the base substrate 1, and a color filter film 3 is on the other side of the base substrate 1 facing away from the thin film transistor 2.

In the COA substrate provided by the embodiment of the present disclosure, the thin film transistor 2 is on a side of the base substrate 1, and the color filter film 3 is on the other side of the base substrate 1 facing away from the thin film transistor 2, that is, the thin film transistor 2 and the color filter film 3 are formed on both sides of the base substrate 1, respectively. When the COA substrate is applied to a liquid crystal display device, the thin film transistor 2 of the COA substrate is generally located on a side of the base substrate 1 close to the backlight of the liquid crystal display device, and the color filter film 3 of the COA substrate is generally located on a side of the base substrate 1 facing away from the backlight of the liquid crystal display device.

In the COA substrate provided by the embodiment of the present disclosure, the thin film transistor 2 and the color filter film 3 are respectively formed on both sides of the base substrate 1, when a via hole configured to connect the pixel electrode with the source-drain electrode in the thin film transistor 2 is formed, the film layer required to be passed through by the via hole does not include the color filter film, so that a depth of the via hole can be appropriately reduced. When the via hole is in a tapered shape, a diameter of the via hole at an end thereof close to the pixel electrode is correspondingly reduced; therefore, the depth and the diameter of the via hole are both small. After the pixel electrode is formed, a depth and a diameter of the hole in the region where the via hole is located are also small, in this case, when the alignment liquid is coated on the pixel electrode to form the alignment layer, a spreading resistance of the alignment liquid is correspondingly reduced, so that the alignment liquid is uniformly spread to obtain an alignment layer having a uniform thickness, thereby alleviating unevenness defects on display brightness or display chromaticity due to the uneven thickness of the alignment layer of the liquid crystal display device. As shown in FIG. 1, the pixel electrode 27 is located at a side of the thin film transistor facing away from the base substrate 1, and it is electrically connected to the thin film transistor 2 through a via hole 28 passing through the passivation layer 26.

It can be understood that, referring to FIG. 2, the COA substrate generally includes a non-display area A and a display area B. The display area B generally includes m sub-pixel units, and each sub-pixel unit includes a light transmitting portion B1 and a light non-transmitting portion B2. Metal signal lines in the COA substrate are densely collected in the non-display area of the COA substrate, and the thin film transistor 2 in the COA substrate is located in the light non-transmitting portion B2 of the display area B, referring to FIGS. 5 and 7.

When the COA substrate is located on a light-exiting side of a liquid crystal display device, that is, the COA substrate is easy to be directly irradiated by ambient light, the non-display area of the COA substrate has a severe metal reflection phenomenon, which is easy to reduce display quality of the liquid crystal display device in which the COA substrate is located. In order to alleviate the defect phenomenon of severe reflection in the non-display area of the COA substrate due to the metal signal line, referring to FIG. 2 to FIG. 4, in the COA substrate provided by the embodiments of the present disclosure, a portion of the color filter film 3 corresponding to the non-display area includes a single-layered color filter film or a double-layered color filter film. The single-layered color filter film is a blue color filter layer 4; and the double-layered color filter film is a red color filter layer 6 and a blue color filter layer 4 which are stacked. In this embodiment, the red color filter layer 6 and the blue color filter layer 4 are stacked, which means that an orthographic projection of the red color filter layer 6 on the base substrate 1 coincides with an orthographic projection of the blue color filter layer 4 on the base substrate 1, however, a stacked order of the red color filter layer 6 and the blue color filter layer 4 is not particularly limited, the red color filter layer 6 may be close to the base substrate 1 or the blue color filter layer 4 may be close to the base substrate 1.

Because the blue color filter layer 4, the red color filter layer and the blue color filter layer which are stacked, both have a very low light transmittance, the embodiment of the present disclosure disposes the blue color filter layer 4, or the red color filter layer 6 and the blue color filter layer 4 which are stacked, in the non-display area, on the side of the base substrate 1 facing away from the thin film transistor 2, that is, a side of the COA substrate where ambient light can be incident on, so that the ambient light can be effectively shielded by the blue color filter layer 4, or, the red color filter layer 6 and the blue color filter layer 4 which are stacked, thereby preventing the ambient light from being irradiated onto the metal signal line to cause severe reflection. Moreover, reflectivity of the blue color filter layer 4, reflectivity of the red color filter layer 6 and the blue color filter layer 4 which are stacked are much smaller than that of the metal material. Therefore, the defect of severe reflection in the non-display area of the COA substrate due to the metal signal line can be well alleviated in the COA substrate having the above structure.

It is to be noted that in the display area B of the COA substrate, the color filter film 3 adopts different structures corresponding to the light transmitting portion B1 and the light non-transmitting portion B2 of the display area B, respectively. For example, corresponding to the m sub-pixel units in the display area B, the color filter film 3 is divided into m color filter portions which are in a one-to-one correspondence with the sub-pixel units.

Each of the color filter portions includes a single-layered color filter film corresponding to the light-transmitting portion B1 of a corresponding sub-pixel unit, that is, a single-layered color filter film is formed, in the light-transmitting portion B1 corresponding to each of the sub-pixel units, on the side of the base substrate 1 facing away from the thin film transistor 2. In addition, referring to a distribution manner of a conventional RGB color mode, the single-layered color filter film described above includes a red color filter layer 6, a green color filter layer 5 or a blue color filter layer 4.

At least n color filter portions further include a double-layered color filter film corresponding to the light non-transmitting portion B2 of the corresponding sub-pixel unit, the double-layered color filter film is a stacked layer including a red color filter layer and a blue color filter layer; wherein m is equal to or greater than n.

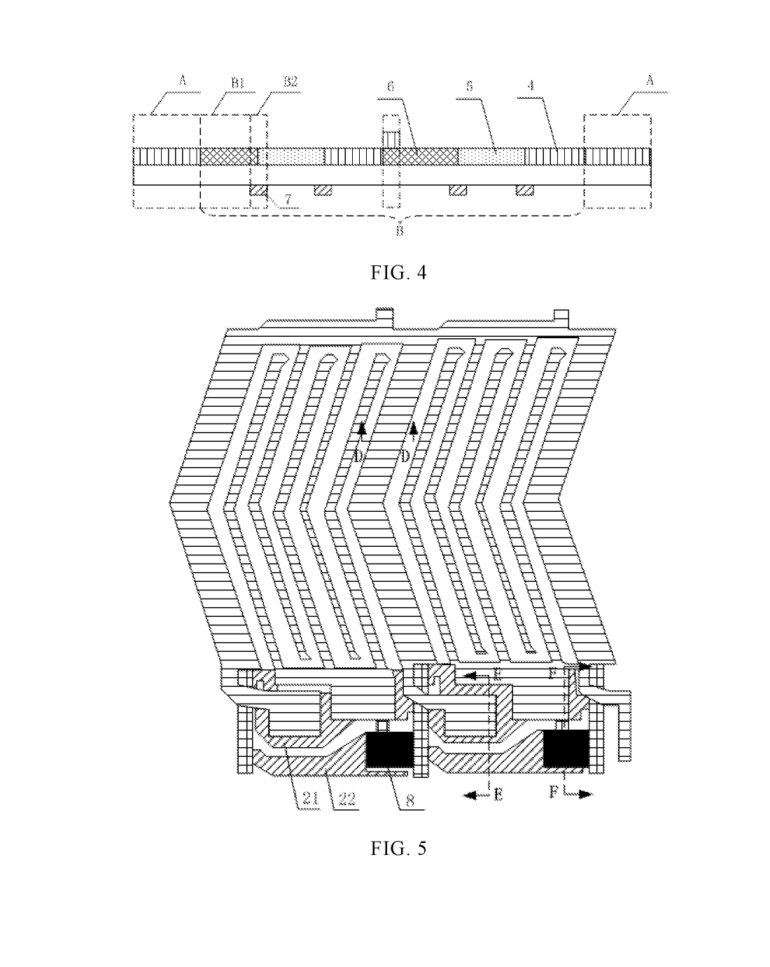

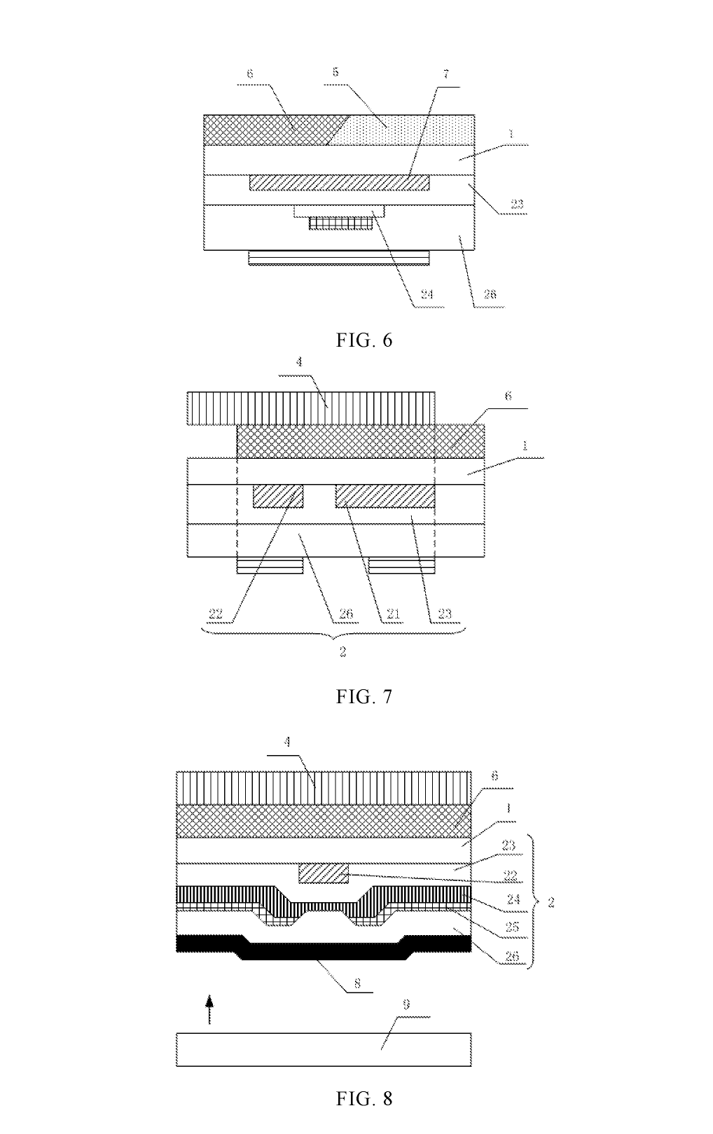

It should be noted that, referring to FIG. 3, m is equal to n refers to that a stacked layer including a red color filter layer and a blue color is formed, in the light non-transmitting portion B2 corresponding to each sub-pixel unit, on the side of the base substrate 1 facing away from the thin film transistor 2. Referring to FIG. 4, m is greater than n refers to that a stacked layer including a red color filter layer and a blue color filter layer is formed, in the light non-transmitting portion B2 corresponding to n sub-pixel units, on the side of the base substrate 1 facing away from the thin film transistor 2, while a color single-layer is formed in the light non-transmitting portion B2 corresponding to other (m−n) sub-pixel units. In this case, a light-shielding metal 7 or a black matrix or the like, may be formed in the light non-transmitting portion B2 corresponding to the other (m−n) sub-pixel units, on the side of the base substrate 1 facing the thin film transistor 2. For example, referring to FIG. 5 and FIG. 6, when a gate electrode 22 of the thin film transistor is usually formed on the base substrate 1, a common electrode 21 is generally formed in the same layer as the gate electrode 22, and the gate electrode 22 is formed with metal material, during fabricating the gate electrode 22, a light-shielding metal 7 may be formed in the same layer as the gate electrode in the light non-transmitting portion of the display area in the COA substrate, without adding additional process. The light-shielding metal 7 is employed to allow the light non-transmitting portion of the display area in the COA substrate to be light shielded, so that the color filter film located on the other side of the base substrate 1 correspondingly only adopts a single-layered color filter film.

In the embodiment of the present disclosure, a double-layered color filter film is in the light non-transmitting portion B2 of the display area in the COA substrate, and the double-layered color filter film is formed by stacking the red color filter layer 6 and the blue color filter layer 4, and a stacked layer including the red color filter layer 6 and the blue color filter layer 4 has a low light transmittance, and is configured to shield light in the light non-transmitting portion B2 of the display area in the COA substrate, so that the double-layered color filter film stacked by the red color filter layer 6 and the blue color filter layer 4 can be served as a black matrix, without adding a black matrix fabrication process in the fabrication of the COA substrate, which simplifies the fabrication process of the COA substrate.

In order to ensure the electrical performance of the thin film transistor, referring to FIG. 8, in the COA substrate provided by the embodiment of the present disclosure, a light shielding layer 8 is provided on a side of the thin film transistor 2 facing away from the base substrate 1, and an orthographic projection of the light shielding layer 8 on the base substrate 1 covers an orthographic projection of the thin film transistor 2 on the substrate 1. In this way, when the COA substrate is located on a light-exiting side of the liquid crystal display device, that is, when the thin film transistor 2 in the COA substrate faces the backlight 9 in the liquid crystal display device, the light shielding layer 8 can be configured to block optical signal incident thereon from a side of the light shielding layer 8 facing away from the thin film transistor, that is, to block light signal emitted from the backlight 9, thereby preventing the thin film transistor 2 from being irradiated by the light signal emitted from the backlight 9, and avoid the electrical performance of the thin film transistor 2 to be affected.

It is to be noted that, referring to FIGS. 5 and 8, the thin film transistor 2 generally includes a gate electrode 22, an insulation layer 23, an active layer 24, a source-drain electrode 25, and a passivation layer 26 which are stacked on the base substrate 1. The light shielding layer 8 is provided on the side of the thin film transistor 2 facing away from the base substrate 1. For example, the light shielding layer 8 is formed on a side of the passivation layer 26 facing away from the base substrate 1. In addition, the light shielding layer 8 may be, for example, made of a material having a light shielding property, such as a metal material, a resin material, or a light shielding adhesive or the like.

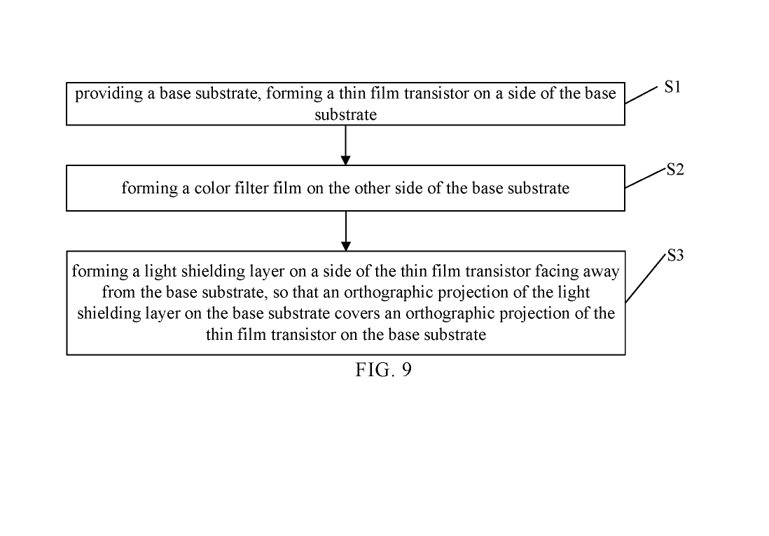

The embodiments of the present disclosure further provide a manufacturing method of a COA substrate, for manufacturing the COA substrate provided by the above embodiments. Referring to FIG. 9, the manufacturing method of the COA substrate includes:

S1, providing a base substrate, forming a thin film transistor on a side of the base substrate;

S2, forming a color filter film on the other side of the base substrate.

The beneficial effects that can be achieved by the manufacturing method of the COA substrate provided by the embodiments of the present disclosure are the same as those of the COA substrate provided by the above embodiments, and are not described herein.

It should be noted that the COA substrate generally includes a display area and a non-display area, the display area generally includes m sub-pixel units, and each of the sub-pixel units includes a light transmitting portion and a light non-transmitting portion.

When the COA substrate is located on the light-exiting side of the liquid crystal display device, that is, the COA substrate is easy to be directly irradiated by the ambient light, the non-display area of the COA substrate has a severe metal reflection phenomenon, which is easy to reduce the display quality of the liquid crystal display device in which the COA substrate is located. In order to solve the defect phenomenon of severe reflection in the non-display area of the COA substrate due to the metal signal line, in the above S2, forming the color filter film on the other side of the base substrate includes: forming a blue color filter layer, in a portion of the base substrate corresponding to the non-display area, on the other side of the base substrate; or forming a stacked layer by stacking a red color filter layer and a blue color filter layer in sequence, in a portion of the base substrate corresponding to the non-display area, on the other side of the base substrate; or forming a stacked layer by stacking a blue color filter layer and a red color filter layer in sequence, in a portion of the base substrate corresponding to the non-display area, on the other side of the base substrate.

Because the blue color filter layer, the stacked red and blue color filter layers both have a very low light transmittance, in the embodiment of the present disclosure, by employing the blue color filter layer 4, or, the red color filter layer 6 and the blue color filter layer 4 which are stacked to be in the non-display area on the side of the base substrate 1 facing away from the thin film transistor 2, that is, a side of the COA substrate where ambient light can be incident on, so that the ambient light can be effectively shielded by the blue color filter layer 4, or, the red color filter layer 6 and the blue color filter layer 4 which are stacked, thereby preventing the ambient light from being irradiated onto the metal signal line to cause severe reflection. Moreover, reflectivity of the blue color filter layer, reflectivity of the red color filter layer 6 and the blue color filter layer 4 which are stacked are much smaller than that of the metal material. Therefore, the defect phenomenon of severe reflection in the non-display area of the COA substrate due to the metal signal line can be alleviated in the COA substrate having the above structure.

In the display area of the COA substrate, the color filter film adopts different manufacturing methods corresponding to the light transmitting portion and the light non-transmitting portion of the display area. For example, in the above step S2, forming the color filter film on the other side of the base substrate includes: forming a single-layered color filter film in the light transmitting portion of each sub-pixel unit; and forming a double-layered color filter film in the light non-transmitting portion of at least n sub-pixel units, and the double-layered color filter film being a red color filter layer and a blue color filter layer which are stacked; wherein m is equal to or greater than n.

In the embodiment of the present disclosure, a double-layered color filter film is in the light non-transmitting portion of the display area in the COA substrate, and the double-layered color filter film is formed by stacking the red color filter layer and the blue color filter layer. A stacked layer including the red color filter layer and the blue color filter layer has a low light transmittance, and is configured to shield light in the light non-transmitting portion of the display area in the COA substrate, so that the double-layered color filter film stacked by the red color filter layer and the blue color filter layer can be served as a black matrix, without adding a black matrix fabrication process in the manufacture of the COA substrate, which simplifies the manufacturing process of the COA substrate.

In order to ensure the electrical performance of the thin film transistor, referring to FIG. 9, the manufacturing method of the COA substrate further includes: S3, forming a light shielding layer on a side of the thin film transistor facing away from the base substrate, so that an orthographic projection of the light shielding layer on the base substrate covers an orthographic projection of the thin film transistor on the base substrate.

In this case, when the COA substrate is located on a light-exiting side of the liquid crystal display device, that is, when the thin film transistor in the COA substrate faces the backlight in the liquid crystal display device, the light-shielding layer can be configured to effectively block the light signal incident thereon from a side of the light-shielding layer facing away from the thin film transistor, that is, to block the light signal emitted from the backlight, thereby preventing the thin film transistor from being irradiated by the light signal emitted from the backlight, and avoiding the electrical performance of the thin film transistor to be affected.

The embodiments of the present disclosure further provide a display panel including the COA substrate provided by any one of the above embodiments. The COA substrate in the display panel has the same advantages as the COA substrate in the above embodiments, and details are not described herein.

The embodiments of the present disclosure further provide a display device including a backlight and the display panel provided by the above embodiment. In the COA substrate of the display panel, the color filter film is located on a side of the base substrate facing away from the backlight. The display panel in the display device has the same advantages as the display panel in the above embodiment, and details are not described herein.

The display device provided by the above embodiments may be any product or component having a display function, such as a mobile phone, a tablet computer, a television, a display, a notebook computer, a digital photo frame, or a navigator.

The above is only an exemplary embodiment of the present disclosure, and is not intended to limit the scope of the present disclosure. The scope of the present disclosure is defined by the appended claims.

1. A color filter on array (COA) substrate comprising a base substrate, a thin film transistor being on a side of the base substrate, a color filter film being on the other side of the base substrate facing away from the thin film transistor.

2. The COA substrate according to claim 1, wherein the COA substrate comprises a non-display area, a portion of the color filter film corresponding to the non-display area comprises: a single-layered color filter film or a double-layered color filter film,
wherein the single-layered color filter film is a blue color filter layer, and the double-layered color filter film is a red color filter layer and a blue color filter layer which are stacked.

3. The COA substrate according to claim 1, wherein the COA substrate comprises a display area, the display area comprises m sub-pixel units, each of the sub-pixel units comprises a light transmitting portion and a light non-transmitting portion, the color filter film comprises m color filter portions in a one-to-one correspondence with the sub-pixel units,
each of the color filter portions comprises a single-layered color filter film corresponding to the light transmitting portion of a corresponding sub-pixel unit; and
at least n color filter portions further comprise a double-layered color filter film corresponding to the light non-transmitting portion of a corresponding sub-pixel unit, wherein the double-layered color filter film is a red color filter layer and a blue color filter layer which are stacked, wherein, m and n are positive integers, and m is equal to or greater than n.

4. The COA substrate according to claim 1, wherein a light shielding layer is on a side of the thin film transistor facing away from the base substrate, and an orthographic projection of the light shielding layer on the base substrate covers an orthographic projection of the thin film transistor on the base substrate.

5. A manufacturing method of a color filter on array (COA) substrate, comprising:
providing a base substrate, forming a thin film transistor on a side of the base substrate; and
forming a color filter film on the other side of the base substrate.

6. The manufacturing method of the COA substrate according to claim 5, wherein the COA substrate comprises a non-display area,
forming the color filter film on the other side of the base substrate comprises:
forming a blue color filter layer, in a portion of the base substrate corresponding to the non-display area, on the other side of the base substrate; or
forming a red color filter layer and a blue color filter layer which are stacked in this order, in a portion of the base substrate corresponding to the non-display area, on the other side of the base substrate; or
forming a blue color filter layer and a red color filter layer which are stacked in this order, in a portion of the base substrate corresponding to the non-display area, on the other side of the base substrate.

7. The manufacturing method of the COA substrate according to claim 5, wherein the COA substrate comprises a display area, the display area comprises m sub-pixel units, each of the sub-pixel units comprises a light transmitting portion and a light non-transmitting portion,
forming the color filter film on the other side of the base substrate comprises:
forming a single-layered color filter film in the light transmitting portion of each of the sub-pixel units;
forming a double-layered color filter film in the light non-transmitting portion of at least n of the sub-pixel units, the double-layered color filter film being a red color filter layer and a blue color filter layer which are stacked, wherein, m and n are positive integers, m is equal to or greater than n.

8. The manufacturing method of the COA substrate according to claim 5, wherein the manufacturing method further comprises:
forming a light shielding layer on a side of the thin film transistor facing away from the base substrate so that an orthographic projection of the light shielding layer on the base substrate covers an orthographic projection of the thin film transistor on the base substrate.

9. A display panel comprising the COA substrate according to claim 1.

10. A display device comprising a backlight and the display panel according to claim 9, wherein in the COA substrate of the display panel, the color filter film is located on the side of the base substrate facing away from the backlight.

11. The COA substrate according to claim 1, further comprising a pixel electrode, wherein the pixel electrode is located at a side of the thin film transistor facing away from the base substrate and is electrically connected to the thin film transistor.

12. The COA substrate according to claim 1, further comprising a passivation layer between the pixel electrode and the thin film transistor, and the pixel electrode is connected to the thin film transistor by a via hole passing though the passivation layer.

13. The COA substrate according to claim 3, wherein the single-layered color filter film has a color selected from a group consisting of red, green, and blue.

14. The manufacturing method of the COA substrate according to claim 5, further comprising forming a pixel electrode at a side of the thin film transistor facing away from the base substrate, wherein the pixel electrode is electrically connected to the thin film transistor.

15. The manufacturing method of the COA substrate according to claim 7, wherein the single-layered color filter film has a color selected from a group consisting of red, green, and blue.
